(19) United States
(12) Patent Application Publication
(10) Pub. No.: US 2012/0008265 A1
(43) Pub. Date: Jan. 12, 2012

(54) ELECTRONIC DEVICE

(75) Inventors: Atsushi Tanaka, Osaka (JP); Takashi Asano, Osaka (JP)

(73) Assignee: SANYO ELECTRIC CO., LTD., Osaka (JP)

(21) Appl. No.: 13/178,250

(22) Filed: Jul. 7, 2011

(30) Foreign Application Priority Data
Jul. 7, 2010 (JP) 2010-155018

(51) Int. Cl. H05K 7/00

(52) U.S. Cl. 361/679.01

(57) ABSTRACT

In an electronic device comprising a device body, an opening is formed in the bottom surface of the device body, a seesaw member is slidingly supported on an internal peripheral surface of the opening by a pivot, and the state of the seesaw member can be changed between a storing state in which both end portions of the seesaw member are stored in the opening and a projecting state in which the first end portion, of both end portions, opposing the main surface is deeply buried into the opening and the second end portion on the main surface side projects from the bottom surface of the device body. On the other hand, in the device body and/or the seesaw member, a restraint mechanism to stop the seesaw member in the projecting state and a release mechanism to release the seesaw member are arranged. The position changing mechanism to change the mounting position of the device body includes the seesaw member, the restraint mechanism, and the release mechanism.

Japanese Patent Application No. 2010-155018 filed on Jul. 7, 2010 serving as base of the priority claims in the present application is included in disclosure by reference.

### TECHNICAL FIELD OF THE INVENTION

The present invention relates to an electronic device such as projector, digital photo frame, or digital camera having a device body in which a light-emitting unit and/or a light incident unit are arranged.

### BACKGROUND ART

In an electronic device of this type, a light-emitting unit is an image display unit such as an optical projection lens arranged in a projector or a liquid display panel which is provided in a digital photo frame. Also, the light incident unit is an optical photographing lens arranged in a digital camera. Conventionally, in these electronic devices, when the device body is placed on a horizontally extending mounting surface in a normal position, the optical axis of the optical lens and the screen of an image display unit are normally set in a horizontal direction.

However, in the projector, when the device body is placed on the mounting surface in a normal position, part of the image projected from the optical lens onto the screen may be disadvantageously blocked by the mounting surface. In an electronic device such as a digital photo frame having an image display unit, when the device body is placed on the mounting surface in a normal position, the image projected on the screen of the image display unit is hardly visible to the user.

Therefore, conventionally, independently from the electronic device, a support table such as a cradle or a stand that can change the position of the device body is provided, and the device body is attached to the support table to change the position of the device body.

### SUMMARY OF THE INVENTION

The electronic device according to the present invention includes a device body, a light-emitting unit and/or a light incident unit in the main surface serving as a front surface or a rear surface of the device body, also a position changing mechanism to change the mounting position of the device body is provided on the bottom surface of the device body. In this case, an opening is formed on the bottom surface of the device body, a seesaw member is slidingly supported on an internal peripheral surface of the opening by a pivot extending almost parallel to both the main surface and the bottom surface, and the seesaw member is slid around the pivot to make it possible to change the state of the seesaw member between a storing state in which both end portions of the seesaw member are stored in the opening and a projecting state in which the first end portion, of both end portions, opposing the main surface is deeply buried in the opening and the second end portion on the main surface side projects from the bottom surface of the device body. On the other hand, in the device body and/or the seesaw member, a restraint mechanism to stop the seesaw member with in projecting state and a release mechanism to release the seesaw member in the projecting state, are provided. The position changing mechanism includes the seesaw member, the restraint mechanism, and the release mechanism.

### BRIEF DESCRIPTION OF THE DRAWINGS

FIG. 1 is a perspective view of the portable projector according to an embodiment of the present invention when viewed from the front surface side of the portable projector.

FIG. 2 is a perspective view of the portable projector when viewed from the rear surface side of the portable projector.

FIG. 3 is a perspective view along the A-A line shown in FIG. 1.

FIG. 4 is an enlarged diagram of B area shown in FIG. 3, and is a sectional view used in the explanation of the storing state of the seesaw member included in the portable projector.

FIG. 5 is a sectional view used in the explanation of the projecting state of the seesaw member.

FIG. 6 is a sectional view used in the explanation of the intermediate state in which the seesaw member shifts from the storing state to the projecting state.

FIG. 7 is a perspective view of the seesaw member when viewed from the front surface side of the seesaw member.

FIG. 8 is a perspective view of the seesaw member when viewed from the rear surface side of the seesaw member.

FIG. 9 is a plan view of the seesaw member when viewed from the rear surface side of the seesaw member.

FIG. 10 is a sectional view showing the mounting position of the device body.

FIG. 11 is a sectional view used in the explanation of the projecting state of the seesaw member included in a mobile projector with respect to a modification of the portable projector.

FIG. 12 is a sectional view used in the explanation of the second projecting state of the seesaw member with respect to the portable projector according to the modification.

### DETAILED DESCRIPTION OF PREFERRED EMBODIMENTS

A mode in which the present invention is applied to a portable projector will be described below in detail with reference to the accompanying drawings.

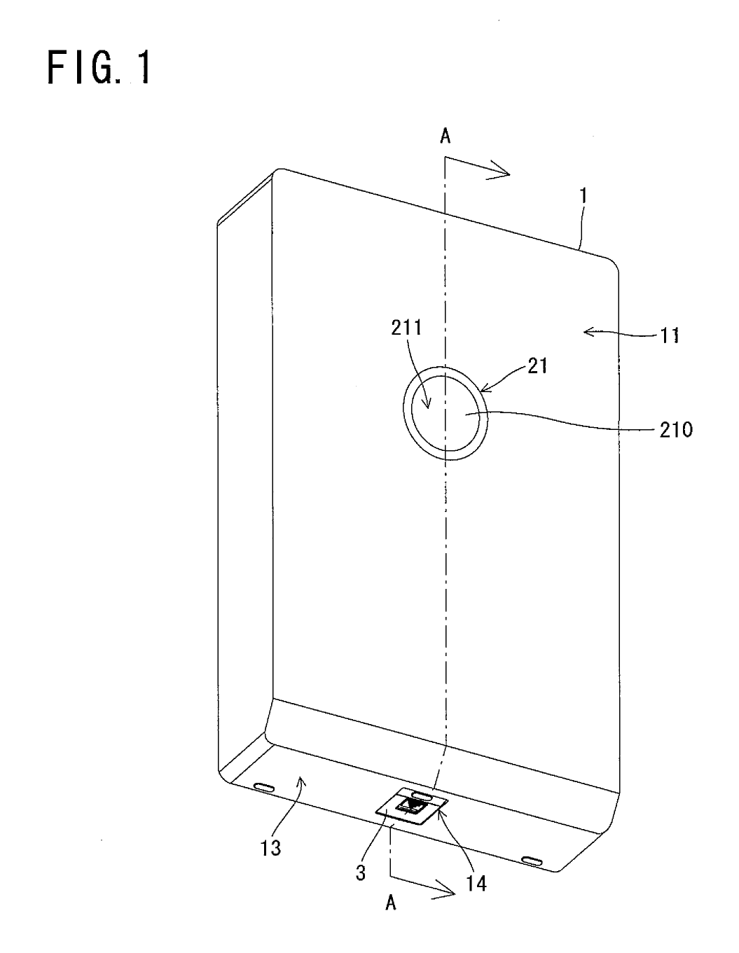

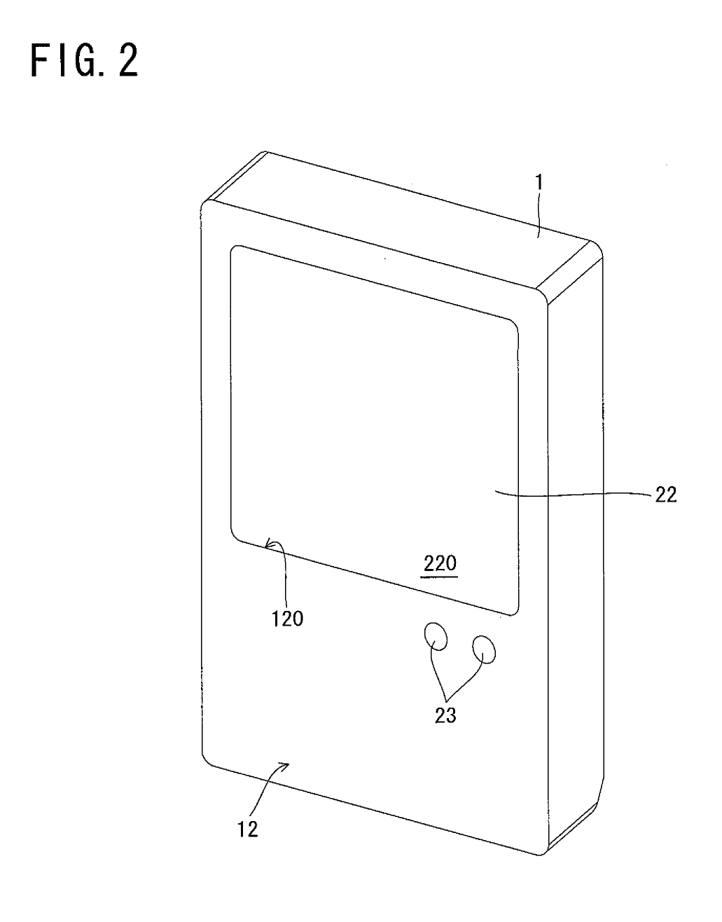

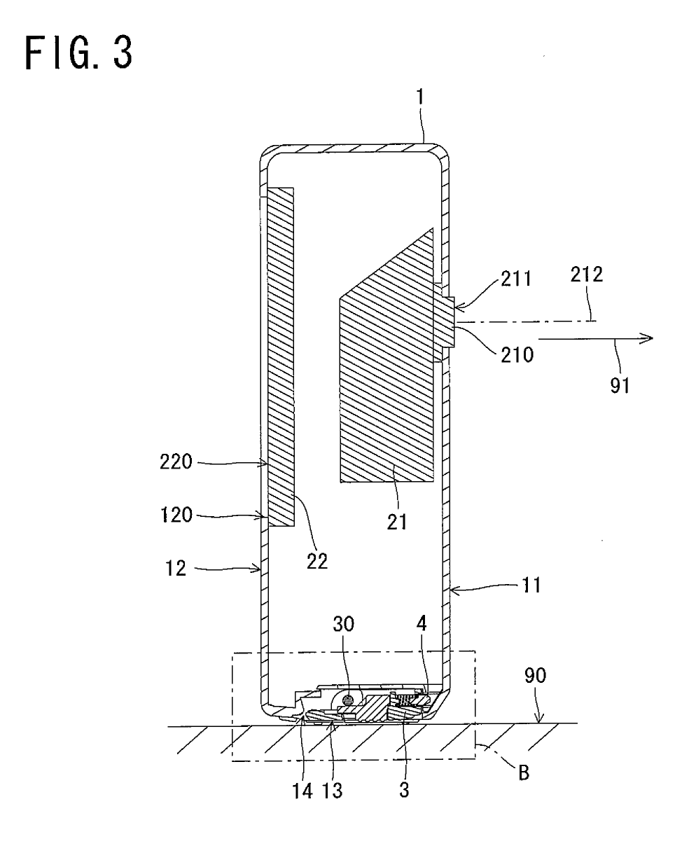

FIG. 1 is a perspective view of a portable projector according to an embodiment of the present invention when viewed from a front surface side of the mobile projector, and FIG. 2 is a perspective view of the portable projector when viewed from a rear surface side of the portable projector. FIG. 3 is a perspective view along the A-A line shown in FIG. 1. As shown in FIGS. 1 to 3, the mobile projector according to the embodiment includes a device body 1, and the device body 1 includes an optical projecting unit 21, and a liquid display panel 22.

The optical projecting unit 21 includes an optical lens 210 to emit light that forms a projected image, and the light-emitting surface 211 of the optical lens exposed on the front surface 11 of the device body 1. As shown in FIG. 3, the optical lens 210 has an attaching position such that, when the device body 1 is placed on the mounting surface 90 in a normal position, the optical axis 212 of the optical lens 210 is set to direction 91 along the mounting surface 90. On the other hand, a screen 220 that displays an image is arranged on the liquid display panel 22, and an image display window 120 that makes it possible to visually check the screen of the liquid display panel 22 from the outside is formed. An operation button 23 is arranged on the rear surface 12 of the device body 1.

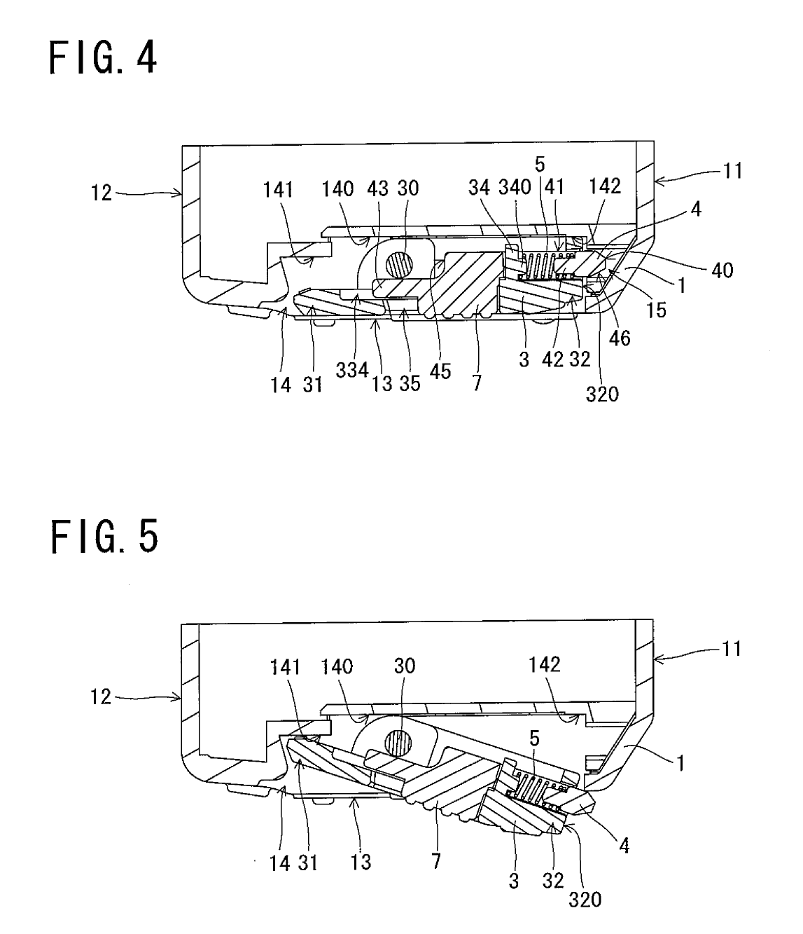

FIG. 4 is an enlarged diagram of B area shown in FIG. 3. As shown in FIG. 4, an opening 14 is formed in the bottom surface 13 of the device body 1 (also see FIG. 1), and a seesaw member 3 is slidingly supported on the internal peripheral surface of opening 14 by a pivot 30 extending almost parallel to both surfaces including the front surface 11 and the bottom surface 13 of the device body 1. Therefore, the seesaw member 3 is slid around the pivot 30 to make it possible to change the state of the seesaw member 3 between the storing state in which, as shown in FIG. 4, both end portions 31 and 32 of the seesaw member are stored in the opening 14 and the projecting state in which, as shown in FIG. 5, the first end portion 31, of both end portions 31 and 32, opposing the front surface 11 of the device body 1 is deeply buried in the opening 14, and the second end portion 32 of the front surface 11 side of the device body 1 projects from the bottom surface 13 of the device body 1.

In this case, on the bottom surface 140 of the opening 14, a first surface area 141 with which the first end portion 31 of the seesaw member 3 is brought into contact when the seesaw member 3 is pivoted to cause the state thereof to shift to the projecting state, and a second surface region 142 with which the second end portion 32 of the seesaw member 3 is brought into contact when the seesaw member 3 is pivoted to cause the state thereof to shift to the storing state, are formed. The first surface area 141 and the second surface region 142 regulate a pivotal range of the seesaw member 3.

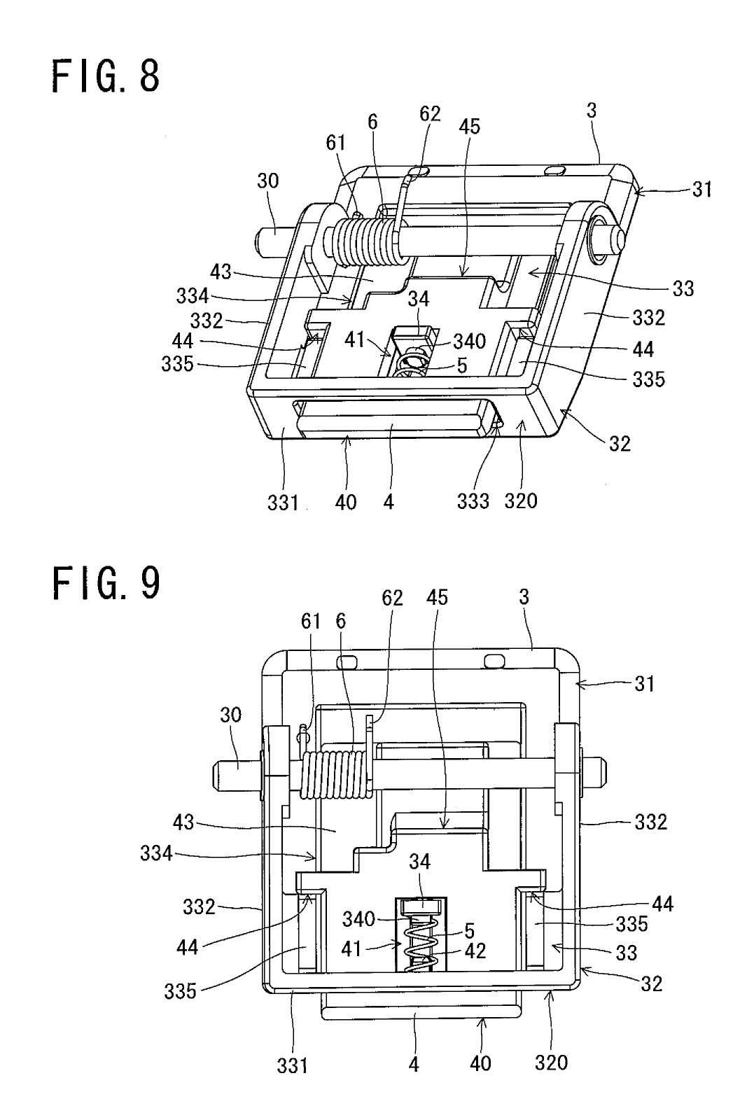

FIG. 7 is a perspective view of the seesaw member 3 when viewed from the front surface side of the seesaw member. FIGS. 8 and 9 are a perspective view and a plan view of the seesaw member 3 when viewed from the rear surface side of the seesaw member. As shown in FIGS. 8 and 9, on the rear surface of the seesaw member 3, a housing portion 33 that houses a plate-like projection 4, a compression coil spring 5, and a torsion spring 6 is concavely formed. More specifically, the housing portion 33 includes a first side wall portion 331 that forms a distal end surface 320 of the second end portion 32 of the seesaw member 3 and one pair of second side wall portions 332 connected to both side edges of the first side wall portion 331 and extending almost perpendicularly to the first side wall portion 331. The pivot 30 penetrates both second side wall portions 332 constituting the housing portion 33 and is supported by the internal peripheral surface of the opening 14.

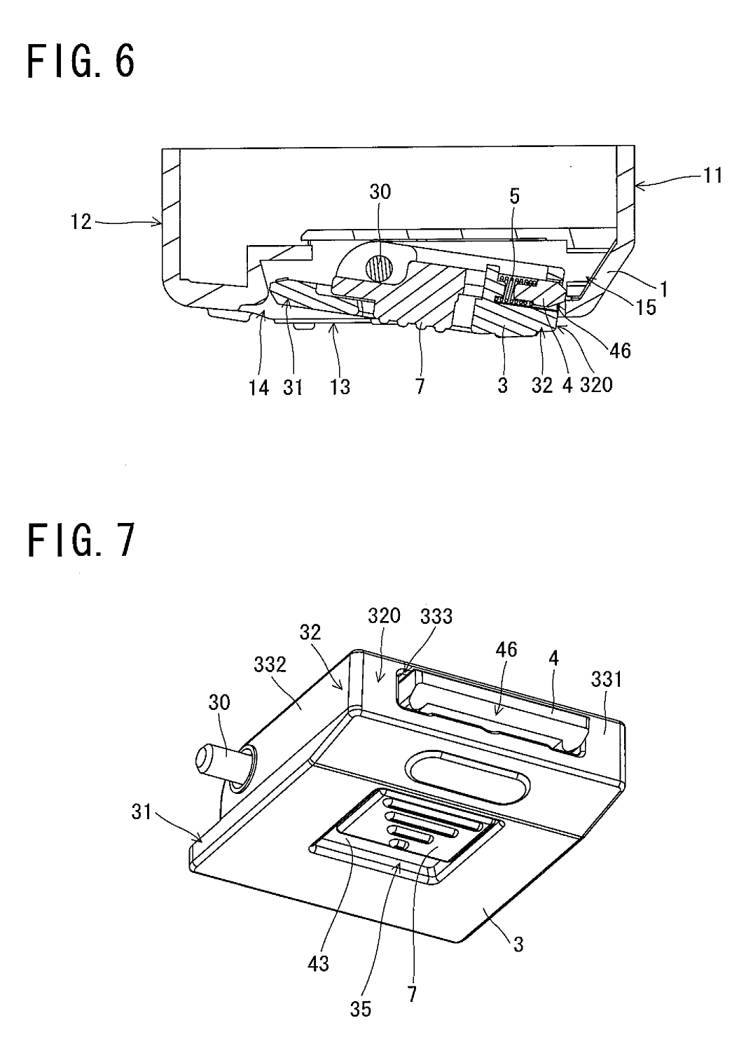

As shown in FIGS. 7 and 8, in the first side wall portion 331 constituting the housing portion 33, an opening 333 that penetrates from the distal end surface 320 of the second end portion 32 to the inside of the housing portion 33 is formed. The projection 4 penetrates the opening 333, and the projection 4 can be reciprocated between an advanced position at which, as shown in FIGS. 4 and 5, the projection 4 advances in front of the distal end surface 320 of the second end portion 32 and a retracted position at which, as shown in FIG. 6, the projection 4 is retracted back of the distal end surface 320 of the second end portion 32.

In this case, as shown in FIGS. 4, 8, and 9, a plate portion 43 is arranged along the bottom surface of the housing portion 33. On the other hand, on the bottom surface of the housing portion 33, the plate portion 43 is slidingly fitted to form a guide trench 334 that regulates the sliding direction of the plate portion 43. The projection 4 is fixed to the plate portion 43 to regulate the moving direction of the projection 4 to the same direction as the sliding direction of the plate portion 43.

On the bottom surface of the housing portion 33, one pair of bump portions 335 are formed in position on both the left and right sides of the projection 4. On the projection 4, a first contact surface 44 that is brought into contact with the bump portions 335 to regulate the advanced position of the projection 4 when the projection 4 is moved to the advanced position, is formed. On the projection 4, on an opposite surface of a distal end 40, a second contact surface 45 that is brought into contact with the pivot 30 when the projection 4 is moved to the retired position is further formed. In this manner, the moving range of the projection 4 is regulated.

In this case, the plate member 43 has dimensions and/or a shape such that a part of the plate member always faces the pivot 30. The second contact surface 45 has a position and/or a shape such that the distal end portion of the projection 4 continuously penetrates the opening 333 even though the second contact surface 45 is brought into contact with the pivot 30. Therefore, the projection 4 fixed to the plate member 43 does not drop out of the seesaw member 3.

As shown in FIGS. 4, 8, and 9, a tongue part 34 projects from the bottom surface of the housing portion 33. On the other hand, in the projection 4, a path 41 through which the tongue part 34 is forced to pass when the projection 4 is moved between the advanced position and the retracted position, is formed. In this case, the path 41 extends in the direction in which the projection 4 moves to have a rectangular shape, and, on the internal peripheral surface of the path 41, and the compression coil spring 5 is interposed between the end face of the projection 4 on the distal end 40 side and the tongue part 34 in a compressed state. In this manner, the projection 4 is biased from the retracted position to the advanced position by the compression coil spring 5 serving as a biasing member. Therefore, when an external force does not act on the projection 4, the projection 4 is held at the advanced position by the biasing force of the compression coil spring 5.

In the embodiment, on the internal peripheral surface of the path 41, projecting portions 42 and 340 are formed on the end face of the projection 4 on the distal end 40 side and on the tongue part 34, respectively, and the projecting portions 42 and 340 are inserted into both end portions of the compression coil spring 5. In this manner, the compression coil spring 5 is prevented from dropping out of the seesaw member 3.

On the other hand, as shown in FIGS. 4 and 7, on the plate portion 43, an operating portion 7 for user operation that moves the projection 4 from the advanced position to the retracted position against the biasing force of the compression coil spring 5 is formed. In this case, in the seesaw member 3, a window 35 that exposes the operating portion 7 to the surface of the seesaw member 3, and the window 35 have a shape such that the operating portion 7 can be slid in the user operation state.

As shown in FIG. 4, on the internal peripheral surface of the opening 14, an engaged portion 15 with the projection 4 is engaged when the seesaw member 3 is set to the storing state, is concavely formed. More specifically, when the seesaw member 3 is set to the storing state, the projection 4 is moved by the biasing force of the compression coil spring 5 to insert the projection 4 into the engaged portion 15. As a result, the projection 4 and the engaged portion 15 are engaged with each other.

A cam surface 46 is formed on the lower surface of the projection 4. In this case, on the cam surface 46, in the process in which the seesaw member 3 shifts from the storing state to the projecting state, an edge of the engaged portion 15 is relatively slid on the cam surface 46. In this manner, the projection 4 is moved from the advanced position to the retracted position against the biasing force of the compression coil spring 5. In this manner, a cam mechanism is constituted by the cam surface 46 of the projection 4 and the edge of the engaged portion 15. In the process in which the seesaw member 3 shifts from the storing state to the projecting state, the projection 4 moves from the advanced position to the retracted against the biasing force of the compression coil spring 5.

As shown in FIGS. 8 and 9, the torsion spring 6 is winded on the pivot 30, and the end portion 61 of the torsion spring 6 extends in the direction opposing the distal end 40 of the projection 4 and is brought into contact with the bottom surface of the housing portion 33. The other end portion 62 of the torsion spring 6 extends in the direction opposing the distal end 40 of the projection 4 and is brought into contact with the bottom surface 140 of the opening 14 (not shown). Therefore, the seesaw member 3 always receives a biasing force to shift the seesaw member 3 to the storing state from the torsion spring 6 serving as a biasing member.

In the portable projector, as shown in FIG. 4, when the seesaw member 3 is set to the storing state, the projection 4 and the engaged portion 15 are engaged with each other. Therefore, despite the intention of the user, the seesaw member 3 is prevented from shifting from the storing state to the projecting state.

When the user presses the first end portion 31 of the seesaw member 3 into the opening 14, the pressing force is converted by operation of the cam mechanism into a force that moves the projection 4 from the advanced position to the retracted position against the biasing force of the compression coil spring 5. Therefore, in the process in which the seesaw member 3 shifts from the storing state to the projecting state, as shown in FIG. 6, the projection 4 moves from the advanced position to the retracted position. In this manner, the engagement between projection 4 and the engaged portion 15 is canceled.

Thereafter, the seesaw member 3 is pivoted around the pivot 30, and the first end portion 31 is deeply buried into the opening 14. On the other hand, the second end portion 32 projects from the bottom surface 13 of the device body 1. As a result, the seesaw member 3 shifts from the storing state to the projecting state as shown in FIG. 5. At this time, the projection 4 moves to the advanced position by the biasing force of the compression coil spring 5. As a result, the projection 4 is brought into contact with the edge of the opening 14 to stop the seesaw member 3 in the projecting state. In this manner, seesaw member 3 is held in the projecting state.

In this case, in the mobile projector, the seesaw member 3 always receives a biasing force that shifts the seesaw member 3 to the storing state from the torsion spring 6. Therefore, the projection 4 is brought into press contact with the edge of the opening 14 by the biasing force of the torsion spring 6. As a result, the seesaw member 3 is prevented from being unstable when the seesaw member 3 is stopped in the projecting state.

On the other hand, the user operates the operating portion 7 to move the projection 4 from the advanced position to the retracted position against the biasing force of the compression coil spring 5 to release the seesaw member 3 in the projecting state. As a result, the seesaw member 3 moves from the projecting state to the storing state.

In this case, in the mobile projector, the seesaw member 3 always receives a biasing force that shifts the seesaw member 3 to the storing state from the torsion spring 6. Therefore, when the seesaw member 3 in the projecting state is released, the seesaw member 3 shifts from the projecting state to the storing state by the biasing force of the torsion spring 6.

In this manner, in the mobile projector, a restraint mechanism to stop the seesaw member 3 in the projecting state and a stopping canceling mechanism to stop the seesaw member 3 in the protecting state are arranged.

In the mobile projector, as shown in FIG. 4, when the seesaw member 3 is set to the storing state, both end portions 31 and 32 of the seesaw member 3 are stored in the opening 14. Therefore, when the device body 1 is placed to cause the bottom surface 13 to face down, as shown in FIG. 3, the device body 1 has a normal position (first mounting position) such that the bottom surface 13 is almost parallel to the mounting surface 90. Therefore, when the device body 1 is set to the first mounting position, the optical axis 212 of the optical lens 210 faces the direction 91 along with the mounting surface 90.

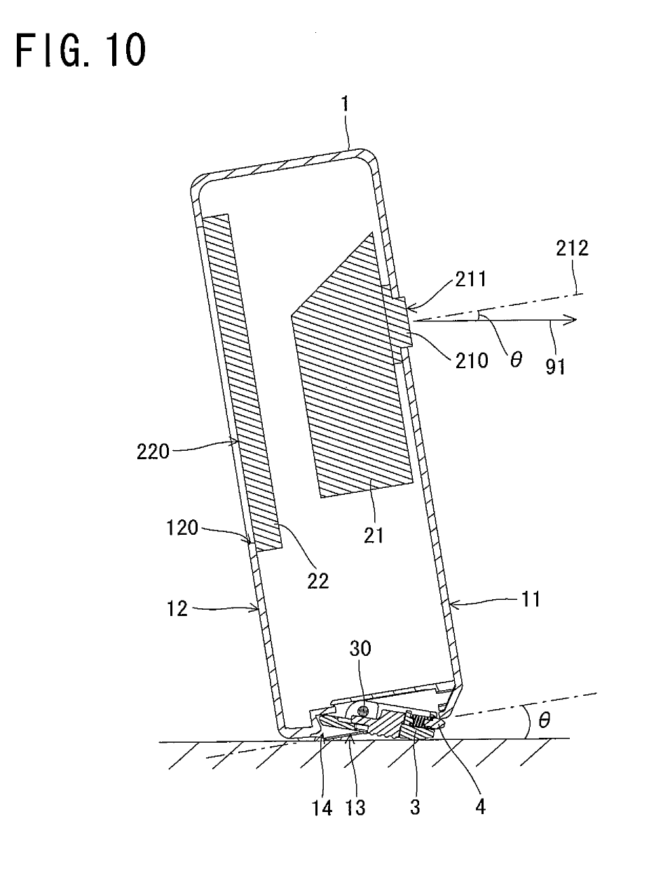

On the other hand, as shown in FIG. 5, when the seesaw member 3 is stopped in the projecting state, the second end portion 32 of the seesaw member 3 projects from the bottom surface 13 of the device body 1. Therefore, when the device body 1 is placed as to cause the bottom surface 13 to face down, as shown in FIG. 10, the device body 1 has a second mounting position such that the bottom surface 13 is tilted to a predetermined angle θ depending on the projection length of the seesaw member 3 from the bottom surface 13 with respect to the mounting surface 90. As a result, the optical axis 212 of the optical lens 210 obliquely turns up at the predetermined angle θ with respect to the direction 91 along the mounting surface 90.

In this manner, in the mobile projector, a position changing mechanism to change the mounting position of the device body 1 is arranged. According to the portable projector, a change of the mounting position of the device body 1 can be realized by a simple configuration.

According to the portable projector, when a user only presses the first end portion 31 of the seesaw member 3 into the opening 14, the engagement between the projection 4 of the engaged portion 15 is canceled, the seesaw member 3 shifts from the storing state to the projecting state, and the seesaw member 3 is stopped in the projecting state. Furthermore, when the user only operates the operating portion 7 to release the seesaw member 3 in the projecting state, the seesaw member 3 shifts from the projecting state to the storing state. Therefore, the portable projector has high operability for changing the mounting position of the device body 1.

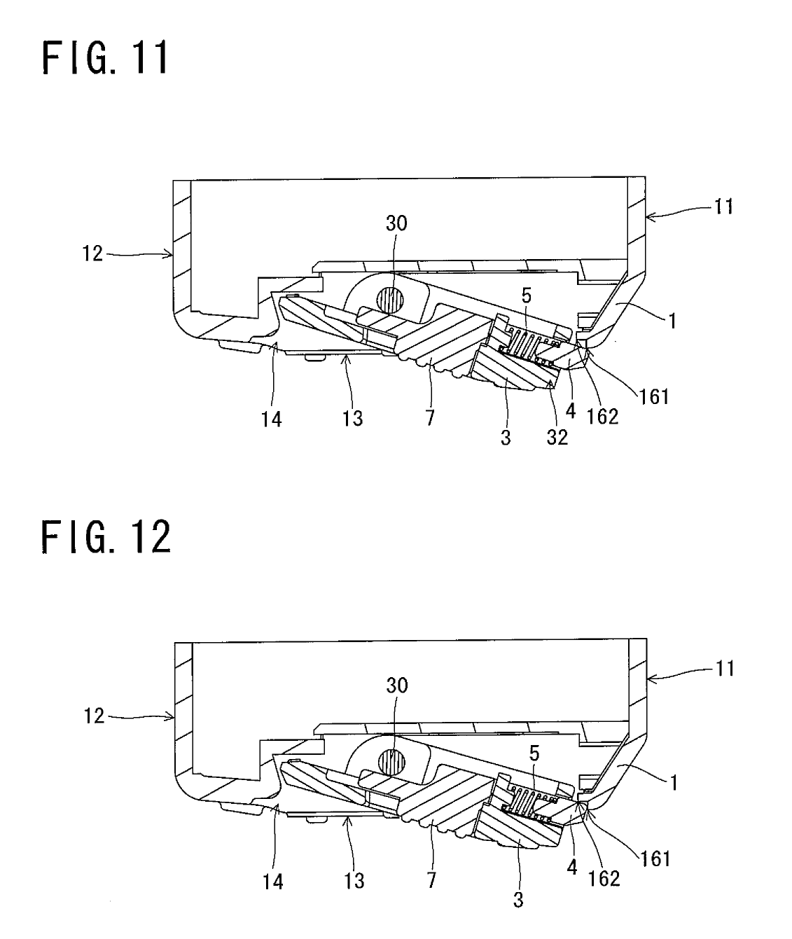

FIG. 11 is an enlarged sectional view showing the same area as area B shown in FIG. 3 with respect to a modification of the portable projector. As shown in FIG. 11, in the portable projector, a step may be formed in an area of the edge of the opening 14 with which the projection 4 is brought into contact to form a first edge portion 161 and a second edge portion 162.

According to the mobile projector of the modification, the first edge portion 161 and the second edge portion 162 can be brought into contact with each other. Therefore, as shown in FIG. 11, the seesaw member 3 can be stopped in the projecting state in which the projection 4 is brought into contact with the second edge portion 162 as shown in FIG. 11 and a second projecting state in which the projection 4 is brought into contact with the second edge portion 162 as shown in FIG. 12. In this case, the projection lengths of the seesaw member 3 from the bottom surface 13 of the device body 1 in both projecting states are different from each other. Tilt angles of the optical axis 212 of the optical lens 210 with respect to the direction 91 along the mounting surface 90 in both projecting states are different from each other. Therefore, the position of the device body 1 can be changed into two or more steps.

In the mobile projector according to the modification, in an area of the edge of the opening 14 with which the projection 4 is brought into contact, a plurality of steps may be provided to form a plurality of edge portions.

The configurations of the portions of the present invention are not limited to this embodiment, and the configurations can be variously changed without departing from the technical essence and scope of the invention. For example, the restraint mechanism to stop the seesaw member 3 in the projecting state and the release mechanism to release the seesaw member 3 with the projecting state are not limited to the configurations of the embodiment. The mechanisms can also be variously changed without departing from the technical essence and scope of the invention.

The portable projector may have a configuration in which the compression coil spring 5 and/or the torsion spring 6 are not provided. In this case, in the configuration in which the compression coil spring 5 is not provided, moving the projection 4 between the advanced position and the retracted position is executed by operation of the operating portion 7 performed by the user. In the configuration in which the torsion spring 6 is not provided, shifting the seesaw member 3 from the projecting state to the storing state is executed by pressing the second end portion 32 made by the user.

The various configurations of the position changing mechanisms employed in the portable projector can be applied to various electronic devices such as a digital photo frames and a digital cameras having an optical photographic unit. In the digital photo frame, a light-emitting unit is configured by an image display unit such as a liquid crystal display panel mounted on the digital photo frame.

The various configurations of the position changing mechanisms employed in the portable projector can also be applied to various electronic devices each having a light-emitting unit such as a normal digital camera having an optical photographic lens and an electronic device in which a light-emitting unit and/or a light incident unit is arranged on the rear surface of the device body.

What is claimed is:

1. An electronic device comprising a device body, a light-emitting unit and/or a light incident unit is arranged on the main surface serving as a front surface or a rear surface of the device body is arranged, and a position changing mechanism to change the mounting position of the device body is arranged on the bottom surface of the device body, wherein
an opening is formed in the bottom surface of the device body, a seesaw member is slidingly supported in an internal peripheral surface of the opening by a pivot extending almost parallel to both the main surface and the bottom surface, the seesaw member is slid around the pivot to make it possible to change a state of the seesaw member between a storing state in which both end portions of the seesaw member are stored in the opening and a projecting state in which the first end portion, of both end portions, opposing the main surface is deeply buried in the opening and the second end portion on the main surface side projects from the bottom surface of the device body, a restraint mechanism to stop the seesaw member in the projecting state and a release mechanism to release the seesaw member in the projecting state are arranged in the device body and/or the seesaw member, and the position changing mechanism includes the seesaw member, the restraint mechanism, and the release mechanism.

2. The electronic device according to claim 1, wherein a projection that can be reciprocated between an advanced position in which the projection advances in front of the distal end surface of the second end portion and a retracted position in which the projection is retracted to the back of the distal end surface of the second end portion, is arranged at the second end portion of the seesaw member, the seesaw member is set to the projecting state, the projection moves to the advanced position to bring the projection into contact with an edge of the opening to stop the seesaw member in the projecting state, the projection moves to the retracted position to release the seesaw member in the projecting state, and both the restraint mechanism and the release mechanism are configured by the projection.

3. The electronic device according to claim 2, wherein the seesaw member, a biasing member that biases the projection from the retracted position to the advanced position and an operation unit for user operation that moves the projection from the advanced position to the retracted position against a biasing force of the biasing member are arranged.

4. The electronic device according to claim 2, wherein an engaged portion with which the projection is engaged when the projection moves to the advanced position when the seesaw member is set in the storing state is arranged in the device body, cam mechanisms are formed in the projection and the engaged portion, and, in the process in which the seesaw member shifts from the storing state to the projecting state, by operation of the cam mechanisms, the projection moves from the advanced position to the retracted position against the biasing force of the biasing member.

5. The electronic device according to claim wherein, in the device body, a biasing member that biases the seesaw member to move the seesaw member to the storing state is arranged.
